(19) United States
(12) Patent Application Publication
(10) Pub. No.: US 2025/0047064 A1
(43) Pub. Date: Feb. 6, 2025

(54) ELECTROLUMINESCENCE DEVICE

(71) Applicant: Taiwan-Asia Semiconductor Corporation, Hsinchu City (TW)

(72) Inventor: Kun-Li LIN, Hsinchu City (TW)

(21) Appl. No.: 18/654,690

(22) Filed: May 3, 2024

(30) Foreign Application Priority Data
Jul. 31, 2023 (TW) 112128596

(51) Int. Cl. H01S 5/042; H01S 5/02; H01S 5/0234; H01S 5/183

(52) U.S. Cl. CPC H01S 5/0422; H01S 5/0213; H01S 5/0234; H01S 5/183; H01S 2304/04

(57) ABSTRACT

An electroluminescence device, including an epitaxial layer, a first contact electrode, a bonding layer, a substrate, a first metal pad, a second contact electrode and a second metal pad, is provided. The epitaxial layer has a trench which vertically divides the epitaxial layer into a first region and a second region so that the first region and the second region are separated from each other. The first contact electrode is disposed over the epitaxial layer and has an aperture. The bonding layer is disposed over the first contact electrode. The substrate is disposed over the bonding layer. The first metal pad is disposed below the first region and extends vertically to be electrically connected to the first contact electrode. The second contact electrode is disposed below the second region. The second metal pad is disposed below the second region with the second contact electrode therebetween.

### CROSS-REFERENCES TO RELATED APPLICATIONS

This application claims priority to Taiwan Patent Application No. 112128596 filed on Jul. 31, 2023, which is hereby incorporated by reference in its entirety.

### BACKGROUND OF THE INVENTION

### Field of the Invention

The present invention relates to an electroluminescence device, especially an electroluminescence device including an epitaxial layer with a trench.

### Descriptions of the Related Art

Electroluminescence (EL) devices, such as vertical cavity surface emitting laser (VCSEL) devices and light-emitting diode (LED) devices, etc., are widely used in consumer electronics as light sources. The main structure of the electroluminescence device is made by epitaxy, and in order to achieve better heat dissipation, it is often made in the form of a flip-chip structure. To ensure the pick-and-place yield of the surface mount technology (SMT) of the flip-chip, the P-side pad (P-pad) and the N-side pad (N-pad) of the electroluminescence device will be designed to be leveled and over the epitaxial layer.

However, after the electroluminescence device is subsequently bonded to the package substrate, the substrate of the electroluminescence device and the package substrate have different coefficients of thermal expansion due to the different compositions of the materials from one another. As a result, the epitaxial layer or dielectric layer of the electroluminescence device may be fractured by stress, resulting in damage to the electroluminescence device.

Given this, the present invention proposes an electroluminescence device capable of solving the above problems.

### SUMMARY OF THE INVENTION

The objective of the present invention is to provide an electroluminescence device that separates the epitaxial layer between the P-side pad and the N-side pad so as to prevent the epitaxial layer or dielectric layer from being fractured by stress after the electroluminescence device is boned onto the package substrate. In addition, another objective of the present invention is to prevent leakage current caused by electrical conduction between the P-side metal electrode in contact with the P-type semiconductor and the N-side metal electrode in contact with the N-type semiconductor due to the fractured epitaxial layer or dielectric layer, which results in that the current does not flow through the multiple quantum well (MQW) layer and then the electroluminescence device cannot operate as expected.

To achieve the above objective, the present invention discloses an electroluminescence device, including: a epitaxial layer, having a trench which vertically divides the epitaxial layer into a first region and a second region so that the first region and the second region are separated from each other; a first contact electrode, disposed over the epitaxial layer and has an aperture; a bonding layer, disposed over the first contact electrode; a substrate, disposed over the bonding layer; a first metal pad, disposed below the first region of the epitaxial layer and extending vertically to be electrically connected to the first contact electrode; a second contact electrode, disposed below the second region of the epitaxial layer; and a second metal pad, disposed below the second region of the epitaxial layer with the second contact electrode therebetween.

In an embodiment, the electroluminescence device is a vertical cavity surface emitting laser (VCSEL) flip-chip.

In an embodiment, the substrate is a transparent substrate, e.g., a sapphire substrate.

In an embodiment, the epitaxial layer includes: an N-type epitaxial layer; a multiple quantum well layer, disposed over the N-type epitaxial layer; a P-type epitaxial layer, disposed over the multiple quantum well layer; and two current blocking layers, arranged in the P-type epitaxial layer and being laterally separated from each other by a distance. The first metal pad is disposed below the N-type epitaxial layer in the first region, and the second contact electrode is disposed below the N-type epitaxial layer in the second region. The first contact electrode is disposed over the P-type epitaxial layer in the first region and the P-type epitaxial layer in the second region.

In an embodiment, the epitaxial layer is grown and formed by a metal-organic chemical vapor deposition method or a molecular beam epitaxy method using an III-V group semiconductor material or an II-VI group semiconductor material.

In an embodiment, an energy gap of the epitaxial layer is between 1.3-2.5 eV.

In an embodiment, the trench is formed by a wet etching process or a dry etching process.

In an embodiment, the first region of the epitaxial layer has a vertical through via, and the first metal pad extends vertically along the vertical through via to be electrically connected to the first contact electrode.

In an embodiment, the first metal pad extends vertically along a sidewall of the first region and is electrically connected to the first contact electrode.

In an embodiment, the electroluminescence device further includes a dielectric layer. The dielectric layer includes a first portion, disposed between the first contact electrode and an upper surface of the epitaxial layer, wherein the first portion does not overlap with the first region of the epitaxial layer and the aperture, a second portion, disposed on a sidewall of the first region of the epitaxial layer adjacent to the trench and on two sidewalls of the second region of the epitaxial layer, and a third portion, disposed on a lower surface of the epitaxial layer, wherein the third portion does not overlap with the first metal pad and does not overlap with the second contact electrode.

After referring to the drawings and the detailed description of embodiments described later, those of ordinary skill in the art can understand other objectives of the present invention, as well as the technical means and implementations of the present invention.

### BRIEF DESCRIPTION OF THE DRAWINGS

FIG. 1 is a schematic cross-sectional view of an electroluminescence device according to an embodiment of the present invention;

FIG. 2 is a schematic cross-sectional view of the electroluminescence device of FIG. 1, in which additional portions of the dielectric layer are added; and

FIG. 3 is a schematic cross-sectional view of an electroluminescence device according to another embodiment of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, partial elements not directly related to the present invention are omitted from the illustration, and dimensional proportions among individual elements and the numbers of each element in the accompanying drawings are provided only for ease of understanding but are not intended to limit the actual scale.

The present invention relates to an electroluminescence device, e.g., VCSEL devices and LED devices etc. The epitaxial layer of the electroluminescence device of the present invention has a trench. The trench vertically divides the epitaxial layer into a first region corresponding to the P-side pad and a second region corresponding to the N-side pad, so that the first region and the second region are separated from each other. Therefore, the electroluminescence device of the present invention can prevent the epitaxial layer or the dielectric layer from being fractured by stress after the electroluminescence device is boned onto the package substrate, and can prevent the P-side metal electrode in contact with the P-type semiconductor and the N-side metal electrode of the N-type semiconductor contact from electrical conduction to induce a leakage current which causes the current not to flow through the multiple quantum well (MQW) layer and the electroluminescence device not to operate as expected.

In the following embodiments, the electroluminescence device is a VCSEL device for illustrative purposes. However, a person having ordinary skill in the art can understand that the structural features of the present invention (for example, the epitaxial layer has a trench, etc.) can also be applied to other electroluminescence devices having similar structures such as LED devices, so these electroluminescence devices also fall within the scope of the present invention.

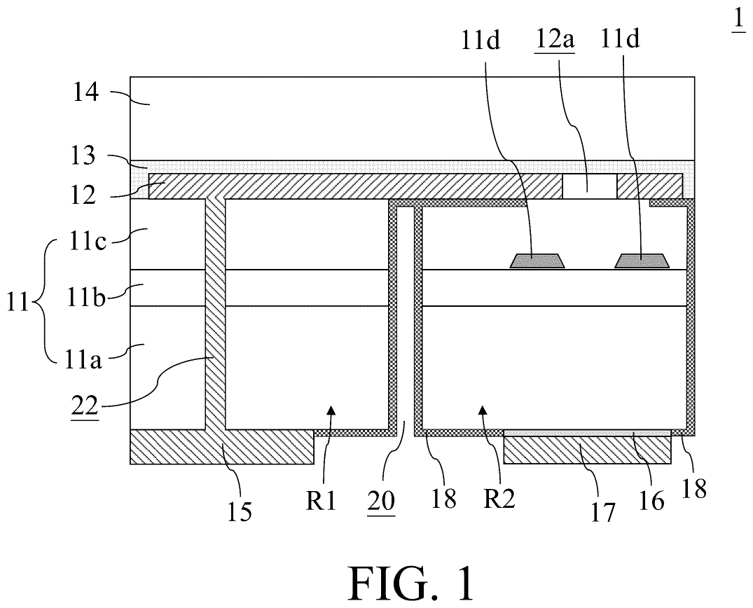

FIG. 1 illustrates an electroluminescence device 1 according to the first embodiment of the present invention, which is made in the form of a flip-chip structure. Specifically, the electroluminescence device 1 is a vertical cavity surface emitting laser (VCSEL) flip-chip. The electroluminescence device 1 includes an epitaxial layer 11, a first contact electrode 12, a bonding layer 13, a substrate 14, a first metal pad 15, a second contact electrode 16 and a second metal pad 17.

The epitaxial layer 11 has a trench 20, which vertically divides the epitaxial layer 11 into a first region R1 and a second region R2. In this way, the first region R1 and the second region R2 can be suitably separated from each other. The trench 20 may be formed by a wet etching process or a dry etching process during the manufacturing process. The trench 20 may not be filled with any material or may be filled with an elastic material, as long as it is capable of withstanding stress to prevent the epitaxial layer or the dielectric layer from being fractured.

The epitaxial layer 11 may be grown and formed by a metal-organic chemical vapor deposition (MOCVD) method or a molecular beam epitaxy (MBE) method using an III-V group semiconductor material or an II-VI group semiconductor material. For example, the epitaxial layer 11 can be formed by stacking the alternating layers of gallium arsenide (GaAs) and aluminum arsenide (AlAs). The energy gap of the epitaxial layer 11 may be between 1.3-2.5 eV.

In addition, in the VCSEL device, the epitaxial layer 11 may include an N-type epitaxial layer 11a, a multiple quantum well layer 11b and a P-type epitaxial layer 11c. Each of the N-type epitaxial layer 11a and the P-type epitaxial layer 11c may be a mirror stack, e.g., a distributed Bragg reflector (DBR). The multiple quantum well layer 11b is disposed over the N-type epitaxial layer 11a, and the P-type epitaxial layer 11c is disposed over the multiple quantum well layer 11b. Furthermore, as shown in FIG. 1, the epitaxial layer 11 further includes two current blocking layers 11d disposed in the P-type epitaxial layer 11c and laterally separated from each other by a distance. Each current blocking layer 11d is an insulating layer, which may be formed by wet oxidation or ion implantation. The two current blocking layers 11d are used to confine the current so that the current can be concentrated through the region therebetween.

The first contact electrode 12 is disposed over the epitaxial layer 11 and includes an aperture 12a. The aperture 12a has a diameter for light to radiate vertically outwards. The first contact electrode 12 is made of a metal material, e.g., gold (Au), titanium (Ti) or platinum (Pt). The bonding layer 13 is disposed over the first contact electrode 12 for bonding the substrate 14 disposed thereon. According to the actual structure, the bonding layer 13 may also be disposed over other layers, e.g., the epitaxial layer 11 or the dielectric layer 18, which will be described later. The bonding layer 13 may include adhesive, dielectric or a combination thereof. For example, the adhesive can use benzo-cyclo-butene (BCB) adhesive, and the dielectric can use silicon nitride (SiNx). The substrate 14 may be a sapphire (Al₂O₃) substrate, but not limited thereto. Depending on the application, any transparent substrate with a light transmittance greater than 90% can be used.

The first metal pad 15 is a P-side pad (P-pad), which is disposed below the first region R1 of the epitaxial layer 11 and extends vertically to be electrically connected to the first contact electrode 12. As shown in FIG. 1, the first region R1 of the epitaxial layer 11 has a vertical through via 22, so the first metal pad 15 may extend vertically along the vertical through hole 22 to be electrically connected to the first contact electrode 12. The material of the first metal pad 15 may be the same as that of the first contact electrode 12, e.g., gold (Au), titanium (Ti) or platinum (Pt). The vertical through via 22 may also be formed by a wet etching process or a dry etching process during the manufacturing process and may be formed at the same process phase as the trench 20.

The second contact electrode 16 is disposed below the second region R2 of the epitaxial layer 11. The second contact electrode 16 is for providing an ohmic contact with the epitaxial layer 11, and it may be made of germanium gold (GeAu), but not limited thereto. The second metal pad 17 is an N-side pad (N-pad), which is disposed below the second region R2 of the epitaxial layer 11 with the second contact electrode 16 therebetween. The material of the second metal pad 17 may be the same as that of the first metal pad 15, e.g., gold (Au), titanium (Ti) or platinum (Pt).

As shown in FIG. 1, the first metal pad 15 is disposed below the N-type epitaxial layer 11a in the first region R1, and the second contact electrode 16 and the second metal pad 17 are disposed below the N-type epitaxial layer 11a in the second region R2. The first contact electrode 12 is disposed over the P-type epitaxial layer 11c in the first region R1 and the P-type epitaxial layer 11c in the second region R2. Since the first region R1 and the second region R2 of the epitaxial layer 11 are separated from each other by the trench 20, under this structure, the present invention can prevent the P-side metal electrode (i.e., the first metal pad 15) in contact with the P-type semiconductor and the N-side metal electrode (i.e., the second metal pad 17) in contact with the N-type semiconductor from electrical conduction to induce a leakage current which causes the current not to flow through the multiple quantum well (MQW) layer and the electroluminescence device not to operate as expected.

The electroluminescence device 1 further includes a dielectric layer 18. The material of the dielectric layer 18 may be silicon dioxide (SiO₂), but not limited thereto. As shown in FIG. 1, the dielectric layer 18 includes a first portion disposed between the first contact electrode 12 and an upper surface of the epitaxial layer 11, a second portion disposed on an adjacent sidewall of the first region R1 of the epitaxial layer 11 adjacent to the trench 20 and on two sidewalls of the second region R2 of the epitaxial layer 11, and a third portion disposed on a lower surface of the epitaxial layer 11. The first portion does not overlap with the first region R1 of the epitaxial layer 11 and the aperture 12a. The third part does not overlap with the first metal pad 15 and does not overlap with the second contact electrode 16.

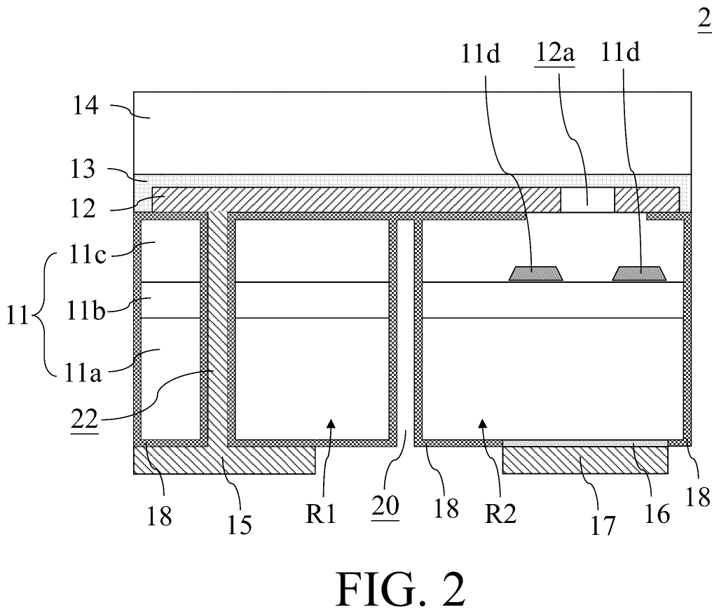

FIG. 2 illustrates an electroluminescence device 2 according to a second embodiment of the present invention. In this embodiment, the dielectric layer 18 of the electroluminescence device 2 is formed not only on the region shown in FIG. 1, but also formed on the upper and lower surfaces and two sidewalls and the side walls of the vertical through via 22 in the first region R1 of the epitaxial layer 11.

It should be noted that the dielectric layer 18 of the electroluminescence device of the present invention may be disposed on any regions for electrical insulation depending on the actual application to prevent current leakage and loss in those regions. Therefore, electroluminescence devices with any possible configuration of dielectric layers are intended to fall within the scope of the present invention.

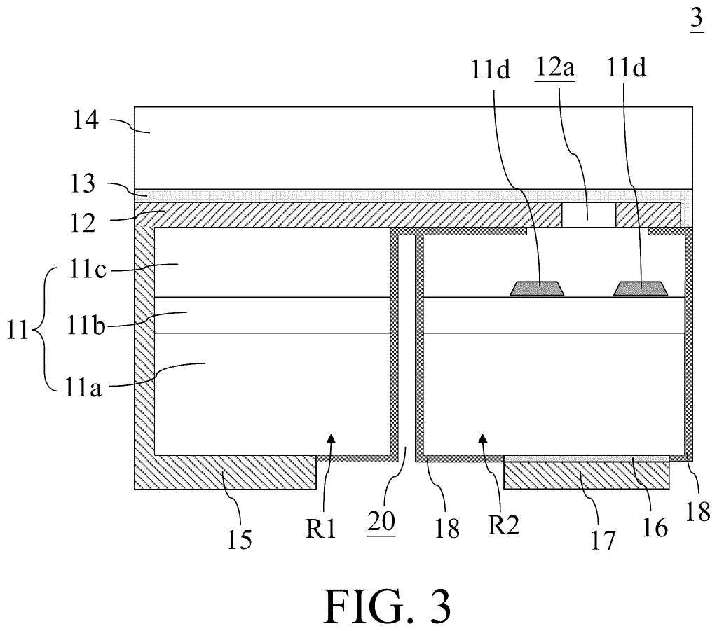

FIG. 3 illustrates an electroluminescence device 3 according to a third embodiment of the present invention. The main difference between the electroluminescence device 3 and the electroluminescence device 1 in FIG. 1 is that the first metal pad 15 extends vertically along a sidewall of the first region R1 to be electrically connected to the first contact electrode 12. Therefore, in this embodiment, there is no vertical through via 22 in the first region R1 of the epitaxial layer 11.

The electroluminescence devices 1, 2, and 3 of the present invention are able to be subsequently bonded onto a package substrate. Depending on the application, the package substrate can be an aluminum nitride (AlN) substrate or a silicon substrate, but is not limited thereto. Since those skilled in the art can easily understand how to bond the electroluminescence device of the present invention to the package substrate, the details will not be described here.

In summary, the electroluminescence device of the present invention divides the epitaxial layer between the P-side pad and the N-side pad, so as to prevent the epitaxial layer or dielectric layer from being fractured by stress after the electroluminescence device is boned onto the package substrate, and avoid the problem that the current does not flow through the multiple quantum well (MQW) layer due to the fracture and then the electroluminescence device cannot operate as expected.

The above embodiments are used only to illustrate the implementations of the present invention and to explain the technical features of the present invention, and are not intended to limit the scope of the present invention. Any modifications or equivalent arrangements that can be easily accomplished by people skilled in this art are considered to fall within the scope of the present invention, and the scope of the present invention should be limited by the claims of the patent application.

What is claimed is:

1. An electroluminescence device, comprising
an epitaxial layer, having a trench which vertically divides the epitaxial layer into a first region and a second region so that the first region and the second region are separated from each other;
a first contact electrode, disposed over the epitaxial layer and having an aperture;
a bonding layer, disposed over the first contact electrode;
a substrate, disposed over the bonding layer;
a first metal pad, disposed below the first region of the epitaxial layer and extending vertically to be electrically connected to the first contact electrode;
a second contact electrode, disposed below the second region of the epitaxial layer; and
a second metal pad, disposed below the second region of the epitaxial layer with the second contact electrode therebetween.

2. The electroluminescence device of claim 1, wherein the electroluminescence device is a vertical cavity surface emitting laser (VCSEL) flip-chip.

3. The electroluminescence device of claim 2, wherein the substrate is a transparent substrate.

4. The electroluminescence device of claim 2, wherein the epitaxial layer comprises:
an N-type epitaxial layer;
a multiple quantum well layer, disposed over the N-type epitaxial layer;
a P-type epitaxial layer, disposed over the multiple quantum well layer; and
two current blocking layers, arranged in the P-type epitaxial layer and being laterally separated from each other by a distance;
wherein the first metal pad is disposed below the N-type epitaxial layer in the first region, and the second contact electrode is disposed below the N-type epitaxial layer in the second region;
wherein the first contact electrode is disposed over the P-type epitaxial layer in the first region and the P-type epitaxial layer in the second region.

5. The electroluminescence device of claim 2, wherein the epitaxial layer is grown and formed by a metal-organic chemical vapor deposition method or a molecular beam epitaxy method using an III-V group semiconductor material or an II-VI group semiconductor material.

6. The electroluminescence device of claim 2, wherein an energy gap of the epitaxial layer is between 1.3-2.5 eV.

7. The electroluminescence device of claim 1, wherein the trench is formed by a wet etching process or a dry etching process.

8. The electroluminescence device of claim 1, wherein the first region of the epitaxial layer has a vertical through via, and the first metal pad extends vertically along the vertical through via to be electrically connected to the first contact electrode.

9. The electroluminescence device of claim 1, wherein the first metal pad extends vertically along a sidewall of the first region and is electrically connected to the first contact electrode.

10. The electroluminescence device of claim 1, further comprising a dielectric layer, wherein the dielectric layer comprises:
a first portion, disposed between the first contact electrode and an upper surface of the epitaxial layer, wherein the first portion does not overlap with the first region of the epitaxial layer and the aperture;
a second portion, disposed on a sidewall of the first region of the epitaxial layer adjacent to the trench and on two sidewalls of the second region of the epitaxial layer; and
a third portion, disposed on a lower surface of the epitaxial layer, wherein the third portion does not overlap with the first metal pad and does not overlap with the second contact electrode.
